(19) United States
(12) Patent Application Publication
(10) Pub. No.: US 2026/0094263 A1
(43) Pub. Date: Apr. 2, 2026

(54) STRUCTURE DETERMINATION

(71) Applicant: Carl Zeiss SMT GmbH, Oberkochen (DE)

(72) Inventors: Thomas KORB, Schwaebisch Gmuend (DE); Johannes DIETERLE, Aalen (DE); Dmitry KLOCHKOV, Schwaebisch Gmuend (DE)

(21) Appl. No.: 19/413,982

(22) Filed: Dec. 9, 2025

Related U.S. Application Data
(63) Continuation of application No. PCT/EP2024/066919, filed on Jun. 18, 2024.

(30) Foreign Application Priority Data
Jun. 19, 2023 (DE) 10 2023 115 975.5

(51) Int. Cl. G06T 7/00; G06T 3/14; G06T 3/60; G06T 5/80; G06T 7/33; H10P 74/20

(52) U.S. Cl. CPC G06T 7/001; G06T 3/14; G06T 3/60; G06T 5/80; G06T 7/337; H10P 74/203; G06T 2207/20012; G06T 2207/30148

(57) ABSTRACT

A method comprises determining a representative ground truth structure provided in a semiconductor sample having a plurality of structures extending mainly in a thickness direction of the sample in a region of interest containing the plurality of structures. At least one adapted image of a milled sample is determined, wherein the at least one adapted image comprises image representations of the structures in the region of interest at different positions in the thickness direction. A transformation is determined by which the image representations at the different positions in the thickness direction of the structures build the ground truth structure, and the transformation is stored for a future application of the transformation to a further sample having the plurality of structures.

### CROSS-REFERENCE TO RELATED APPLICATIONS

The present application is a continuation of, and claims benefit under 35 USC 120 to, international application No. PCT/EP2024/066919, filed Jun. 18, 2024, which claims benefit under 35 USC 119 of German Application No. 10 2023 115 975.5, filed Jun. 19, 2023. The entire disclosure of each of these applications is incorporated by reference herein.

### FIELD

The present application relates to a method carried out at a processing unit and relates to the corresponding processing unit, a computer program comprising program code and a carrier comprising the computer program.

### BACKGROUND

Semiconductor structures are amongst the finest man-made structures and can suffer from different imperfections. Devices for quantitative 3D-metrology, defect-detection or defect review looking for these imperfections. Fabricated semiconductor structures are based on prior knowledge. The semiconductor structures are manufactured from a sequence of layers parallel to a substrate. For example, in a logic type sample, metal lines are run parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average.

A semiconductor wafer typically has a diameter of 300 mm and comprises a plurality of several sites, so called dies, each comprising at least one integrated circuit pattern such as for example for a memory chip or for a processor chip. During fabrication, semiconductor wafers run through about 1,000 process steps, and within the semiconductor wafer, about 100 and more parallel layers are formed, comprising the transistor layers, the layers of the middle of the line, and the interconnect layers and, in memory devices, a plurality of 3D arrays of memory cells. Dimensions, shapes and placements of the semiconductor structures and patters are subject to several influences. In manufacturing of 3D-Memory devices, the processes include etching and deposition. Other process steps such as lithography exposure or implantation can have an impact on the properties of the IC-elements.

The aspect ratio and the number of layers of integrated circuits is constantly increasing and the structures are growing into third (vertical) dimension. The current height of the memory stacks exceeds five microns, in the future this may be up to dozens of microns. In contrast, the features size is becoming smaller. The minimum feature size or critical dimension is below 10 nm, for example 7 nm or 5 nm, and is approaching feature sizes below 3 nm in near future, for 3D NANDS it is 150 nm, for vertical DRAMS around 30 nm. A semiconductor layer has a thickness around 10 nm or less. While the complexity and dimensions of the semiconductor structures generally growing into the third dimension, the lateral dimensions of integrated semiconductor structures are becoming smaller. Therefore, measuring the shape, dimensions and orientation of the features and patterns in 3D and their overlay with relatively high precision can become challenging.

With the increasing desire for the resolution of charged particle imaging systems in three dimensions, the inspection and 3D analysis of integrated semiconductor circuits in wafers is becoming more and more challenging. The lateral measurement resolution of charged particle systems is typically limited by the charged particle beam diameter, sampling raster is adapted accordingly. The sampling raster resolution can be set within the imaging system and can be adapted to the charged particle beam diameter on the sample. A typical raster resolution is 2 nm or below, but the raster resolution limit can generally be reduced with no physical limitation. The charged particle beam diameter has a limited dimension, which generally depends on the charged particle beam operation conditions and lens. The beam resolution is generally limited by approximately half of the beam diameter. The resolution can be below 2 nm, for example even below 1 nm.

### SUMMARY

A desire exists to provide a reliable method for determining and analyzing semiconductor structures in a wafer with high precision.

According to a first aspect, the disclosure provides a method carried out at a processing unit wherein the method comprises the step of determining a representative ground truth structure provided in the semiconductor sample having a plurality of structures extending mainly in a thickness direction of the sample in a region of interest containing the plurality of structures. Furthermore at least one adapted image is determined of a milled sample which was obtained by milling the sample in a region containing the region of interest, wherein the at least one adapted image comprises image representations of the structures in the region of interest at different positions in the thickness direction. Instead of milling any other delayering method may be used, e.g. a laser. Furthermore a transformation is determined by which the image representations at the different positions in the thickness direction of the structures build the ground truth structure. The information of the transformation is stored for a future application of the transformation to a further sample having the plurality of structures. Furthermore the corresponding processing entity is provided comprising a memory and at least one processor wherein the memory comprises instructions executable by the at least one processor and wherein the processing entity is configured to operate as discussed above or as discussed in further detail below.

When the ground truth structure is known and when the at least one adapted image is provided which shows the image representations of the structures, it is possible to determine a transformation by which representations in the different thickness direction are used to represent the ground truth structure. This approach makes it possible to take into account possible image distortions which occur during the generation of the at least one adapted image. Accordingly a relatively precise calibration can be provided which can then be used for the inspection of further structures.

In an aspect, the disclosure provides a computer program comprising program code, wherein the program code is to be executed by at least one processing entity and the execution of the program code causes the at least one processing entity to carry out a method as discussed above or as discussed in further detail below.

In an aspect, the disclosure provides a carrier comprising the computer program wherein the carrier is one of an electronic signal, optical signal, radio signal, and computer readable storage medium.

Other features and aspects of the disclosure may become apparent to one with skill in the art upon examination of the following detailed description and figures. It is to be understood that the features mentioned above and yet to be explained below can be used not only in the respective combinations indicated but also in other combinations. Features of the above-mentioned aspects and embodiments described below may be combined with each other in other embodiments unless explicitly mentioned otherwise.

The foregoing and additional features and effects of the application may become apparent from the following detailed description when read in conjunction with the accompanying drawings in which like reference numerals refer to like elements.

### BRIEF DESCRIPTION OF THE DRAWINGS

FIG. 1 shows a schematic view of a set up where a semiconductor wafer comprises several structures in the thickness direction in the form of channels.

FIG. 2 shows a schematic view of the dual beam system with which a wafer and especially semiconductor structures can be examined.

FIG. 3 shows a schematic view of a method of a method of a volume inspection in a wafer with a slanted cross-section milling and imaging by the dual beam device of FIG. 2.

FIG. 4 shows two examples of cross-section image slices.

FIG. 5 shows a schematic explanation how it is possible in a not optimized approach to determine a geometry of the channel based on a single image.

FIG. 6 shows a further example similar to FIG. 5 where in a two-dimensional situation the sample position of the image representations of the channels might not provide an exact representation of the channel.

FIG. 7 shows a schematic view how an image distortion of an image of the sample may lead to an incorrect position estimation of the channel within the sample volume.

FIG. 8 shows a schematic view how an uncorrected sample rotation of the sample during images may be misinterpreted as a misalignment of the channel

FIG. 9 shows a schematic view of a delayered sample and how the sample with the channel is represented in a wedge image.

FIG. 10 shows a schematic view of how the channels can be grouped in different groups depending on the location in the thickness direction of the wafer.

FIG. 11 shows an example schematic representation of a general grouping in a wedge image when the sample was not correctly aligned and a sample rotation was present during imaging.

FIG. 12 shows a schematic view of a trajectory of the semiconductor structure in 3D space.

FIG. 13 shows a schematic view of how a representative ground truth channel can be generated based on wedge images

FIG. 14 shows a schematic view of how wedge images with image representations of the channels are used to simulate and build the representative ground truth structure.

FIG. 15 shows a schematic view indicating the relationship between a position of the image presentation in the wedged image and the position in the thickness or a depth direction.

FIG. 16 schematically shows how the image representations have to be transformed in order to build the ground truth structure using a folding back mechanism.

FIG. 17 shows a schematic view of a one-dimensional set up with a wedge image of a single column of channels.

FIG. 18 shows a schematic representation of how a channel geometry influences a pitch parameter which is used to fold back the image representation to build the ground truth structure.

FIG. 19 shows a schematic view of a flowchart comprising steps carried out during a calibration workflow in which a transformation is determined.

FIG. 20 shows a schematic view of a method carried out to evaluate a new sample with the determined transformation.

FIG. 21 shows a schematic view of a flowchart of a method carried out by a processing unit to determine a transformation.

FIG. 22 shows a schematic representation of a flowchart comprising the steps used to apply a rotation correction before the transformation is determined.

FIG. 23 shows a schematic representation of a processing entity configured to determine a transformation.

### DETAILED DESCRIPTION

Some examples of the present disclosure generally provide for a plurality of circuits or other electrical devices. All references to the circuits and other electrical devices and the functionality provided by each are not intended to be limited to encompassing only what is illustrated and described herein. While certain labels may be assigned to the various circuits or other electrical devices disclosed, such labels are not intended to limit the scope of operation for the circuits and the other electrical devices. Such circuits and other electrical devices may be combined with each other and/or separated in any manner based on the type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

In the following a method is explained in more detail which allows an extraction of channel traces or other semiconductor structures and especially of the channel tilts and deviations of the channel traces from a straight trace (wiggling) from an image obtained from a delayered sample and based on a representative ground truth structure of the sample. Such an extraction of channel traces and the channel tilts sensitively depends on a proper calibration. Calibration in the present context means that a correct mapping function should be found from the channel positions in a single wedge to a representative channel from a full 3D tomography. Furthermore, the correct application of this transformation to the image of a single wedge imposes very tight desire properties regarding the sample orientation when acquiring a simple wedge since, even a minute rotation would be mistakenly interpreted as a channel tilt. The channels penetrate the semiconductor sample by around 2 μm for a DRAM 5 μm for a NAND, wherein it is a target to determine a tilt of the semiconductor structure, here the channel to be in the range of approximately 1 mrad. The reasonable region of interest (ROI) where the channel information is determined may be between 2 and 5 μm since this size ROI usually contains already more than 100 channels giving enough statistical sampling.

The following disclosure provides a method for a correct detection and correction of sample rotations of a milled or delayered sample before a transformation into a representative channel. Furthermore a robust calibration of the transformation from a single wedge to a representative channel is provided with a representative trace and tilt in the presence of image distortions. These image distortions occur when a single wedge image of the semiconductor sample is generated

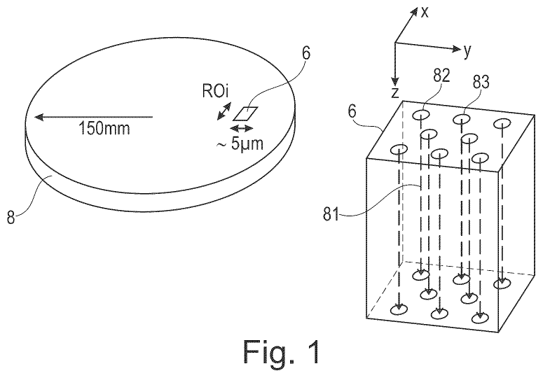

FIG. 1 shows a schematic view of a semiconductor sample 8 where a region of interest 6 is examined to determine whether the desired structure of any semiconductor structure implemented in the semiconductor sample 8 is provided or not and especially how the semiconductor structure looks like. In the example shown the region of interest 6 contains several structures 81, 82 and 83 extending in the thickness direction of the sample wherein the structures can represent channels or other high aspect ratio, HAR structures. It can be assumed that the region of interest 6 contains N different channels. The position of the centroids of each channel over the depth Z can be described as follows:

$${r}_{T , n} ( z ) = ( {x}_{T , n} ( z ) , {y}_{T , n} ( z ) ) \qquad ( 1 )$$

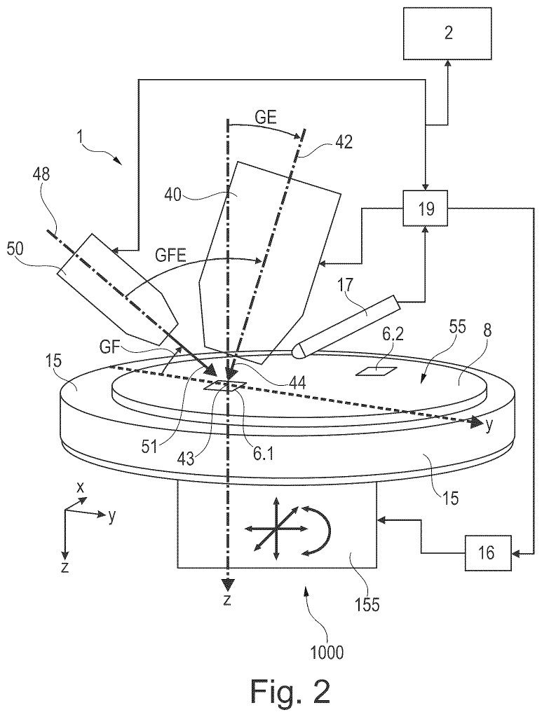

With reference to FIG. 2 a system is shown with which an actual shape of a milled surface is determined. The wafer inspection system 1000 is configured for a slice and imaging method under wedge cut geometry with a dual beam device 1. For a wafer 8, several measurement sites, comprising measurement sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and mechanisms for precision control for a wafer stage such as Laser interferometers are known in the art. A control unit 16 configured to control the wafer stage 155 and to adjust a measurement site 6.1 of the wafer 8 at the intersection point 43 of the dual-beam device 1. The dual beam device 1 is comprising a FIB column 50 with a FIB optical axis 48 and a charged particle beam (CPB) imaging system 40 with optical axis 42. At the intersection point 43 of both optical axes of FIB and CPB imaging system, the wafer surface is arranged at a slant angle GF to the FIB axis 48. FIB axis 48 and CPB imaging system axis 42 include an angle GFE, and the CPB imaging system axis forms an angle GE with normal to the wafer surface 55. In the coordinate system of FIG. 2, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at measurement site 6.1, and secondary particles as well as scattered particles are generated. Particle detector 17 collects at least some of the secondary particles and scattered particles and communicates the particle count with a control unit 19. Other detectors for other kinds of interaction products may be present as well. Control unit 19 is in control of the charged particle beam imaging column 40, of FIB column 50 and connected to a control unit 16 to control the position of the wafer mounted on the wafer support table via the wafer stage 155. Control unit 19 communicates with operation control unit 2, which triggers placement and alignment for example of measurement site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM).

In an example, the dual beam system comprises a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface.

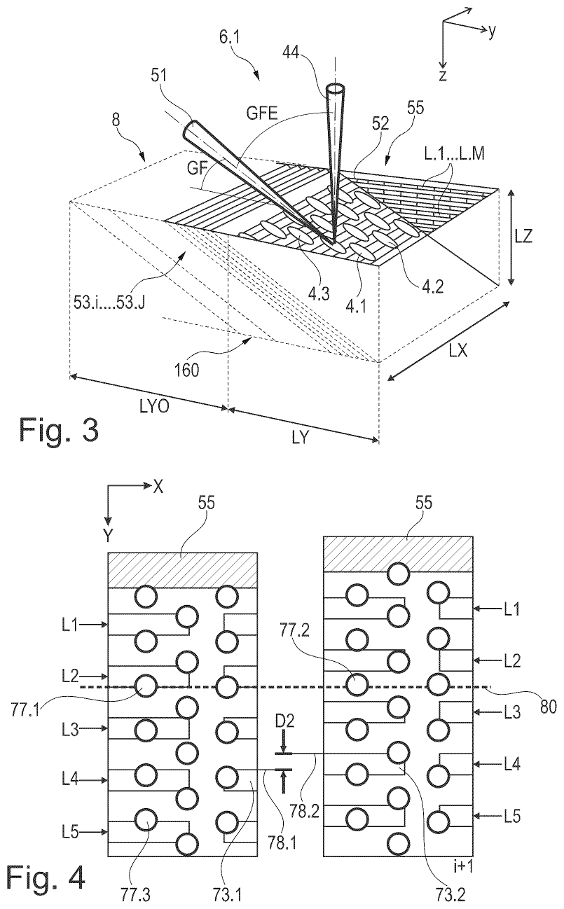

FIG. 3 illustrates further details of the slice and imaging method in the wedge cut geometry. By repetition of the slicing and imaging method in wedge-cut geometry, a plurality of J cross-section image slices comprising image slices of cross-section surfaces 52, 53.i . . . 53.J is generated and a 3D volume image of an inspection volume 160 at an inspection site 6.1 of the wafer 8 at measurement site 6.1 is generated. FIG. 3 illustrates the wedge cut geometry at the example of a 3D-memory stack. The cross-section surfaces 52, 53.1 . . . 53.N are milled with a FIB beam 51 at an angle GF of approximately 30° to the wafer surface 9, but other angles GF, for example between GF=20° and GF=60° are possible as well. FIG. 3 illustrates the situation, when the surface 52 is the new cross-section surface which was milled last by FIB 51. The cross-section surface 52 is scanned for example by SEM beam 44, which is in the example of FIG. 3 arranged at normal incidence to the wafer surface 55, and a high-resolution cross-section image slice is generated. The cross-section image slice comprises first cross-section image features, formed by intersections with high aspect ratio (HAR) structures or vias (for example first cross-section image features of HAR-structures 4.1, 4.2, and 4.3) and second cross-section image features formed by intersections with layers L.1 . . . . L.M, which comprise for example SiO2, SiN— or Tungsten lines. Some of the lines are also called “word-lines”. The maximum number M of layers is typically more than 50, for example more than 100 or even more than 200. The HAR-structures and layers extend throughout most of the volume in the wafer but may comprise gaps. The HAR structures typically have diameters below 160 nm, for example about 80 nm, or for example 40 nm. The cross-section image slices contain therefore first cross-section image features as intersections or cross-sections of the HAR structure footprints at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

FIG. 4 illustrates an ith and (i+1)-th cross-section image slice at an example. The vertical HAR structures appear in the cross-section image slices as first cross-section image features, for example first cross-section image features 77.1, 77.2 and 77.3. Since the imaging charged particle beam 44 is oriented parallel to the HAR structures, the first cross-section image features representing for example an ideal HAR structures would appear at same y-coordinates. For example, first cross-section image features of ideal HAR structures 77.1 and 77.2 are centered at line 80 with identical Y-coordinate of the ith and (i+1)-th image slice. The cross-section image slices further comprise a plurality of second cross-section image features of a plurality of layers comprising for example layers L1 to L5, for example second cross-section image features 73.1 and 73.2 of layer L4. The layer structure appears as segments of stripes along X-direction in the cross-section image slices. The position of these second cross-section image features representing the plurality of layers, here shown layers L1 to L5, however, changes with each cross-section image slice with respect to the first cross-section image features. As the layers intersect the image planes at increasing depth, the position of the second cross-section image features changes from image slice i to image slice i+1 in a predefined manner. The upper surface of layer L4, indicated by reference numbers 78.1, 78.2, are displaced by distance D2 in y-direction. From determining the positions of the second cross-section image features, for example 78.1 and 78.2, the depth map Z(x,y) of a cross-section image can be determined in case of visible horizontal structures in the sample.

By feature extraction of the second cross-section image features, such as edge detection or centroid computation and image analysis, and according to the assumption of the same or similar depth of the second cross-section image features, the determination of the lateral position as well as the relative depth of the first cross-section image features in cross-section image slices is therefore possible with high precision. Due to the planar fabrication techniques involved in the fabrication of a wafer, layers L1 to L5 are at constant depth over a larger area of a wafer. The depth maps of first cross-section image slices can at least be determined relative the depth of second cross-section images features in the M layers. Further details for the generation of the depth maps ZJ(x,y) for the cross-section image slices are described in WO 2021/180600 A1.

A plurality of J cross-section image slices acquired in this manner covers an inspection volume of the wafer 8 at measurement site 6.1 and is used for forming of a 3D volume image of high 3D resolution below for example 10 nm, such as below 5 nm. The inspection volume 160 (see FIG. 3) typically has a lateral extension of LX=LY=5 μm to 15 μm in x-y plane, and a depth LZ of 2 μm to 15 μm below the wafer surface 55. The full 3D volume image generation according to WO 2021/180600 A1 typically involves the milling of cross-section surfaces into the surface 55 of the wafer 8 with a larger extension in y-direction as the extension LY. In this example, the additional area with extension LYO is destroyed by the milling of the cross-section surfaces 53.1 to 53.N. In a typical example, the extension LYO exceeds 20 μm.

The operation control unit 2 (see FIG. 2) is configured to perform a 3D inspection inside an inspection volume 160 in a wafer 8. The operation control unit 2 is further configured to reconstruct the properties of semiconductor structures of interest from the 3D volume image. In an example, features and 3D positions of the semiconductor structures of interest, for example the positions of the HAR structures, are detected by the image processing methods, for example from HAR centroids. A 3D volume image generation including image processing methods and feature based alignment is further described in WO 2020/244795 A1, which is hereby incorporated by reference.

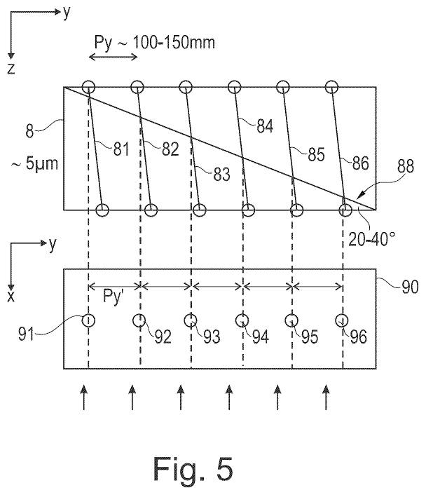

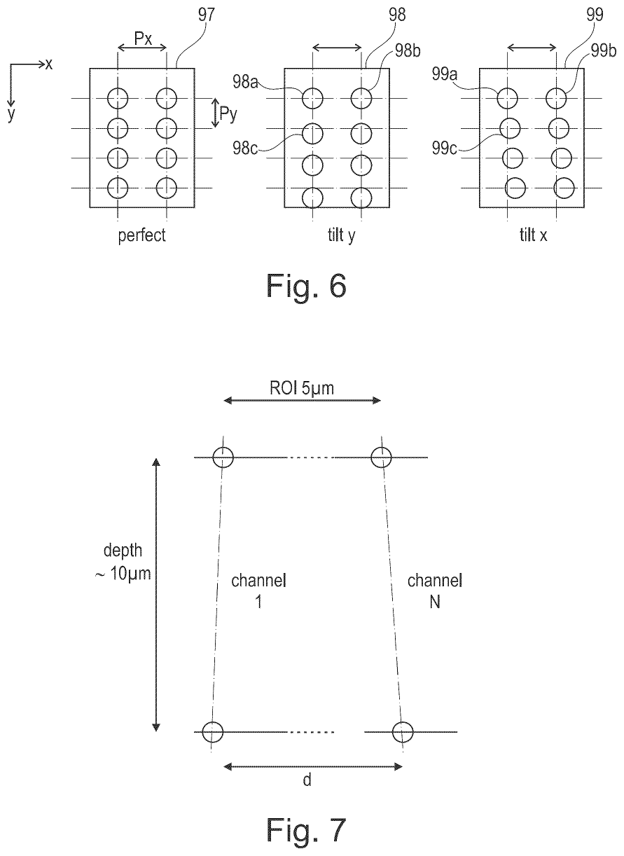

In connection with FIGS. 5 and 6 a first more naïve and not optimized approach for the channel trace and tilt extraction is discussed in more detail and the issues that can occur with this approach. If on a single wedge cutting through the full depth of the sample deviations from the expected perfect grid positions are observed, one could conclude that the channels are not running straight down. FIG. 5 shows a schematic representation of the single wedge including the different channels 81-86 in a single wedge 88. An image 90 representing the wedge comprises the image representations of the channels 91-96 which show the channels at a different depth position in the Z-direction. The dashed lines indicate the positions of the channel cross sections in the wedge image. If the correct vertical alignment is not present the distance or pitch p_{Y} between neighboring image representations 91-96 is different from the nominal pitch.

FIG. 6 shows a further two-dimensional example and the corresponding wedge images 97-99 wherein image 97 shows the pattern for channels which extend fully perpendicular to the un-milled top surface of the sample so that the pitch p_{X} and p_{Y} is the nominal one throughout the image 97. In image 98 a tilt of the channels is assumed in the y-direction so that the general representations 98A, 98B or 98C are not shown at the expected position but are displaced in the y-direction. The same is true for the image representations 99A-99C for a tilt in the x-direction. If it is desired to determine the channel tilt simply based on the images 90, or 97-99 the perfect grid, so the pitch between the different channels has to be known. Furthermore, the image distortions that could lead to distortions in the images shown have to be known and controlled wherein especially the depth dependent distortions have to be known. Secondly any kind of non-controlled sample rotation during the acquisition of the wedge image will influence the results and may be misinterpreted as a channel tilt even though the semiconductor sample was not perfectly aligned during the image acquisition.

For the sake of demonstration a few estimations will be given below. In connection with FIG. 7 it is explained how a change of the magnification with increasing depth will influence the representation of the structures in the image. By way of example a chance of the magnification with depth by 1%/μm over the region of interest of 5 μm and a depth of 10 μm will introduce the following error in the channel tilt measurement. As shown in FIG. 7 the region of interest has a width of 5 μm and a depth of 10 μm and the above change of magnification will lead to the following distance d:

$$d = 5 µm \cdot ( 1 + 10 µm \cdot \frac{1 \%}{µm} ) = 5.05 µm \qquad ( 2 )$$

The computed tilt angle between channel 1 and channel N in the example FIG. 7 will then be:

$${tilt}_{1 , N} = \frac{5.05 µm - 5 µm}{10 µm} = 5 \frac{nm}{µm} = 5 mrad \qquad ( 3 )$$

The size of the error given by equation 3 already introduces a systematic error in the order of magnitude larger than the measurement target of 1 mrad.

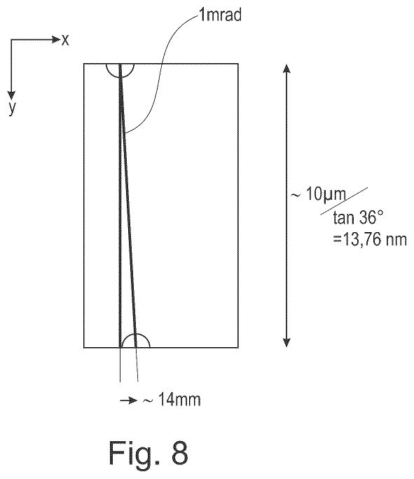

In connection with FIG. 8 an un-corrected sample rotation of 1 mrad with a wedge angle of 36° will be discussed in a situation where a depth of 10 μm is considered. As shown in FIG. 8 with a wedge angle of 36° and a depth of 10 μm a dislocation at the lower bottom of around 14 nm is obtained. Accordingly the situation shown in FIG. 8 leads to an observed channel shift of 14 nm which will be interpreted as channel tilt as follows:

$${tilt}_{x} = \frac{14 nm}{10 µm} = 1.4 mrad \qquad ( 4 )$$

As shown by equation 4 this un-correct sample rotation will again lead to an assumed tilt which is larger than the measurement target of 1 mrad.

Issues discussed here can be overcome in the following way:
First of all, instead of measuring against a perfect grid as in the more naïve approach above the transformation from the single wedge to the ground truth representative channel is calibrated including all repeatable image distortions.
Secondly, an insight on the joint movement of the equivalent channels on the wedge allows for a correction of the sample rotation.

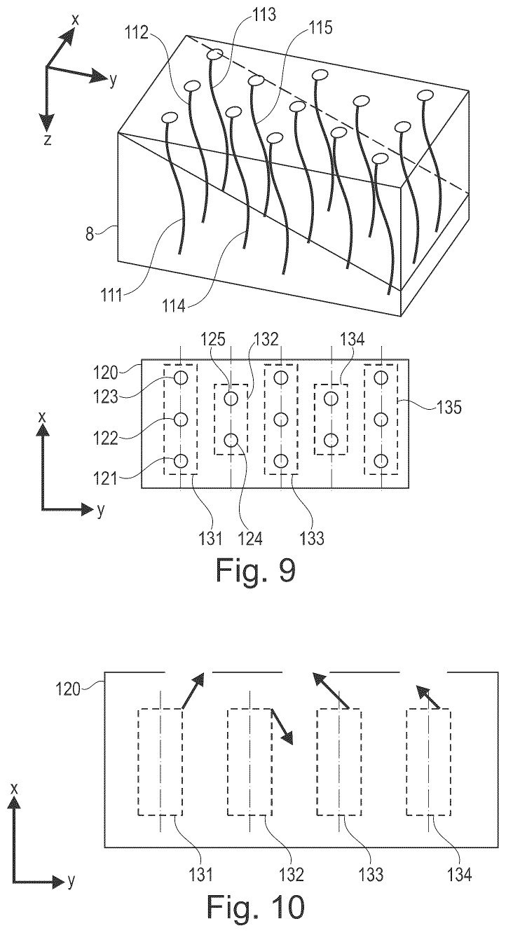

In connection with FIGS. 9-11 the second point of the correction of the sample rotation will be discussed in more detail. In an established manufacturing process the channel traces within the region of interest are very repeatable and the channel-to-channel variations are expected to be small and random. In such a set up the intersections of the channel with the single wedge move in horizontal groups.

FIG. 9 shows an example representation of a sample 8 having different channels 111 to 114. The lower part of FIG. 9 shows the corresponding wedge image 120 with the corresponding image representations 121-125. In such a set up as shown in FIG. 9 the intersections of the channels with the single wedge can be grouped in different horizontal groups such as groups 131, 132, 133, 134 and 135. The image representations of channels 111-113 can be grouped to group 131 and the same way the image representations occurring at another depth position for channels 114 and 115 can be grouped together to group 132. In a perfectly aligned sample 8 with channels of arbitrary but equal traces which are perfectly aligned relative to one another, the different groups representing the channel intersections at the same z depths as marked by the hatched boxes in FIG. 9 are aligned on an axis parallel to the x-axis. FIG. 10 shows such a wedge image 120 with groups 131-134, and depending on the depth direction the boxes or groups move without changing the orientation as shown by the arrows shown in FIG. 10

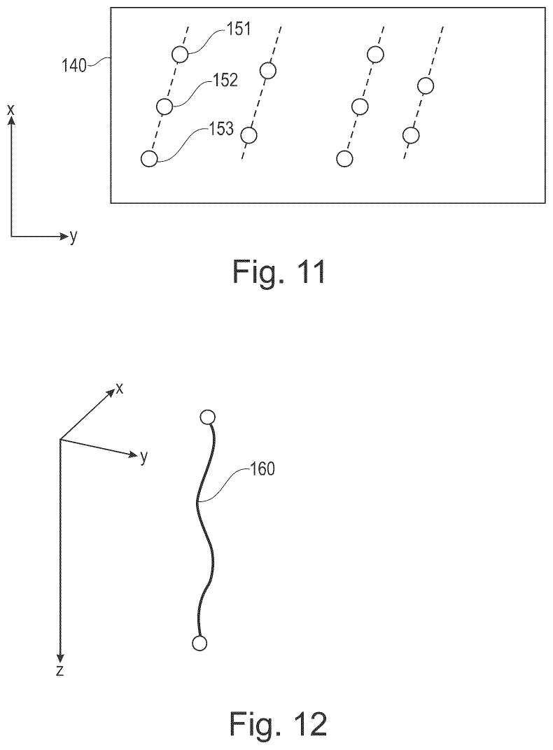

Referring to FIG. 11, a wedge image having grouped image representations such as the representations 151-153 are not aligned along the X-axis, which is an indication that a sample rotation of the sample 8 has been present at image acquisition. Accordingly by grouping the channels together which represent channels at the same depth position and by the orientation of the assembled group it is possible to determine whether a sample rotation has been present during image acquisition. The sample rotation can thus be detected from the wedge images and can be properly corrected by methods such as rotating the image until the axis of these groups are parallel to the x-direction. This can mean that a distorted image such as the image 140 is acquired which is then rotated in order to determine an adapted image where the groups of image representations since representing the channel intersections with the wedge at the same depths are aligned parallel to an edge of the sample. Accordingly a possible two-step process is as follows: In a first step all channel intersections belonging to the same set steps are grouped together in a wedge image and in a second step a rotation correction is applied so that the lines joining channels of the same group are on average parallel to a bounding edge of the sample, here the X-direction or X-axis.

In connection with FIGS. 12-18 the further second aspect is described in more detail, namely the transformation from a single wedge to a ground truth representative channel is calibrated including all repeatable image distortions.

FIG. 12 shows a representative channel which should reflect a common trend of all channels within the region of interest and which can be generated from any reliable measurement such as CD-SAXS (critical dimension small angle x-ray scattering) or transmission electron microscopy, TEM, or 3D tomography. This reliable measurement has to be generated only once and may be used for the further semiconductor samples which were obtained under similar conditions. Acquiring this may be challenging and time consuming so acquiring only once as a calibration reference for the single wedge will save time when it is possible to work with calibrated single wedges afterwards without the need to repeatedly do this challenging and time consuming reference measurements again. The representative ground truth structural channel means a trajectory in the 3D space such as trajectory 160 shown in FIG. 12 which is possibly generated from a sampling in z-direction wherein this trajectory can be explained with the following equation:

$${\underline{r}}_{T} ( z ) = ( {x}_{T} ( z ) , {y}_{T} ( Z ) ) \qquad ( 5 )$$

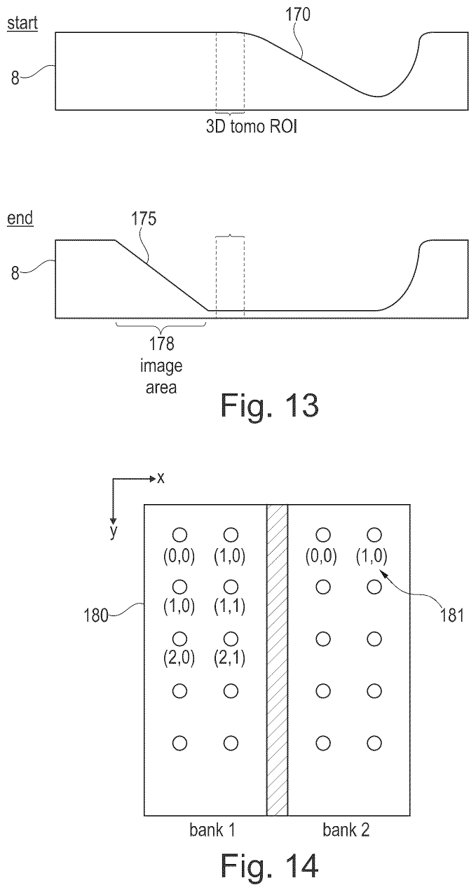

In the following the generation of a representative channel from a 3D tomography is explained in more detail. In case of a 3D tomography the representative channel or ground truth channel would be generated by first running a tomography and then taking a single wedge image of the released wedge as shown in connection with FIG. 13. The sample contains a 3D region of interest where the channels are located and the method starts with an initial trench 170 and ends with a high quality wedge 175 wherein furthermore a wedge image area 178 is shown. The means that the 3D tomography and the wedge are from the same area. From the tomography a set of channel traces n=1, . . . , N is extracted and then the representative or ground truth channel can be calculated as follows:

$${\underline{r}}_{T} ( z ) = \frac{1}{N} {\sum }_{n = 1}^{N} ( {\underline{r}}_{T , n} ( z ) - {〈 {\underline{r}}_{T , n} ( z ) 〉}_{Z} ) \qquad ( 6 )$$

The last term describes the average over the depth z and the first term describes the position of the channel or trace T depending on the z position

This additionally provides a characteristic of how representative r_{T(z)} is for the r_{T,n}(z) through the standard deviation

$${σ}^{2} = \frac{1}{N - 1} {\sum }_{n = 1}^{N} {〈 {( ( {\underline{r}}_{T , n} ( z ) - {〈 {\underline{r}}_{T , n} ( z ) 〉}_{Z} ) - {\underline{r}}_{T} ( z ) )}^{2} 〉}_{z} \qquad ( 7 )$$

Any calibration of the wedge to the representative channel transform is not to be better than

$${σ}^{2} = {σ}_{x}^{2} + {σ}_{y}^{2}$$

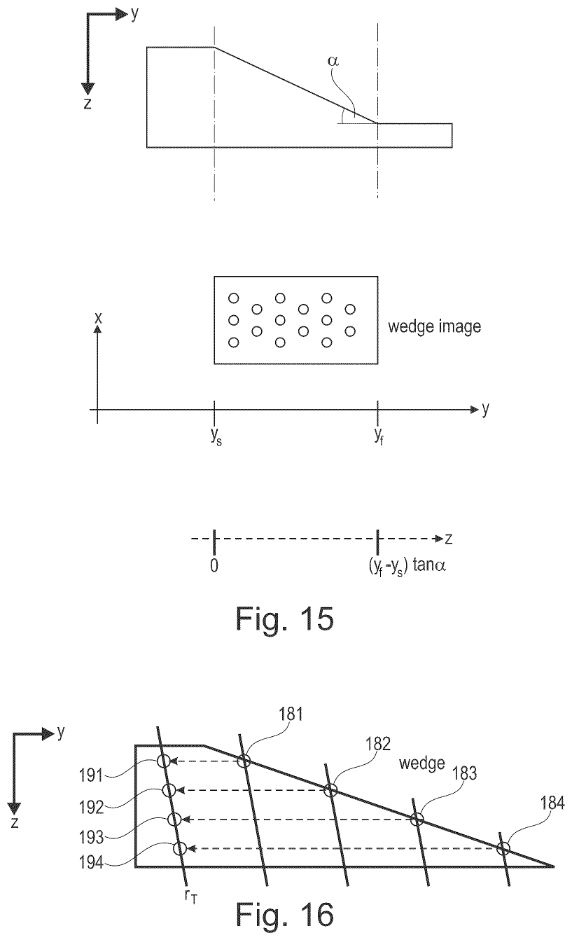

In the following the calibration of the transform will be discussed in more detail. No matter how the representative channel or ground truth channel was generated, this channel will serve as a basis in the following step as calibration target. FIG. 14 shows an image 180 of two memory banks and the wedge image 180 has the grid indices 181. The y-coordinate is linked to the set-depth through the known wedge angle which might be between 20° and 40° as shown by the geometry of FIG. 15 by the following equation:

$$z = ( y - {y}_{s} ) tan α \qquad ( 8 )$$

yₛ being the position where the wedge meets the top surface of the sample.

The task is now to find the optimal transformation of the image representations shown in FIG. 14 to form the ground truth structure. Mathematically, this corresponds substantially to folding back of the image representations to build the ground truth structure

Now the optimal transformation of the

$${( x , y )}_{ij}^{b}$$

is used to form r_{T}(z) which is substantially folding back and correcting distortions.

This is also represented in FIG. 16 where the image representations 181-184 have to be moved using an explicit pitch parameter by which the image representations 181-184 are folded back to representations 191-194 shown in FIG. 16 which then build an assembled ground truth structure which can be compared to the ground truth structure which was generated beforehand. While in the more naïve approach discussed in the introductory part of the detailed description the pitch is assumed to be taken from the design data, it is here a degree of the calibration. Mathematically this can be described as an optimization problem with a penalty function S to be minimized or otherwise optimized. For a 2D wedge grid a simple approach including the linear magnification over the depth distortion the mathematical form can be as follows:

$${{S}_{2 D} = {\sum }_{b} {\sum }_{ij} ( ( {\underline{r}}_{ij}^{b} - i {\underline{p}}_{1} - j {\underline{p}}_{2} - {\underline{r}}_{b} ) - {\underline{r}}_{T} ( ( {y}_{ij}^{b} - {y}_{s} ) tan α ) ) )}^{2} \qquad ( 9 )$$

The first term in equation 9 is the position of the image representation in the wedge image, p₁ and p₂ are the 2D explicit pitch parameters, r_{b} describes an offset parameter describing the spatial positions of different groups and the last term describes the z-coordinate

$$( {y}_{ij}^{b} - {y}_{s} )$$

tan α where the ground auth channel r_{T}(z) is evaluated.

For a perfect cartesian grid and no distortions

$${\underline{p}}_{1} = ( \begin{matrix}Px \\ 0\end{matrix} ) and {\underline{P}}_{2} = ( \begin{matrix}0 \\ Py\end{matrix} )$$

would be the solution of a minimization of S_{2D} with P₁, P₂ and r_{b}.

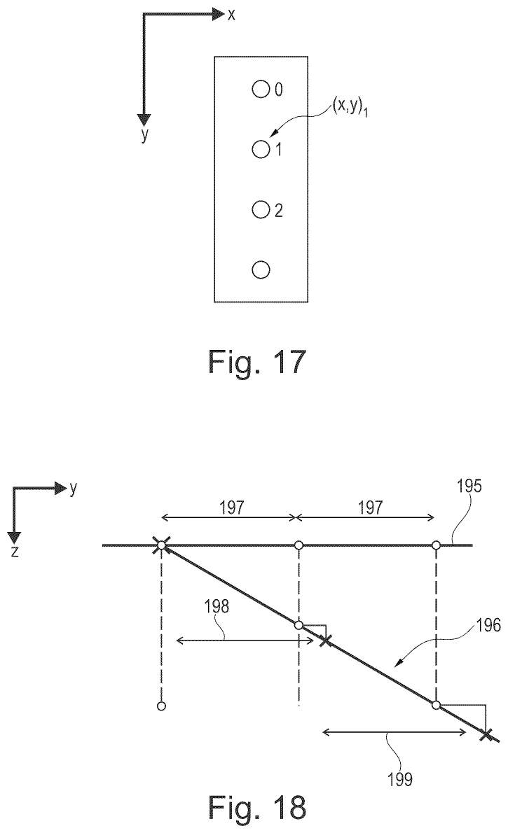

FIG. 17 shows a 1 dimensional set up with a wedge image of a single column and the penalty function as would read as follows:

$${S}_{1 D} = {\sum }_{i} {( {\underline{r}}_{i} - i \underline{p} - {\underline{r}}_{T} ( ( {y}_{i -} {y}_{s} ) tan α ) )}^{2} \qquad ( 10 )$$

One aspect to consider is that for a linear magnification over the depth the explicit pitch P will not be the design grid pitch that contains the magnification and correctly considers the distortion in the optimal transform.

$${r}_{w} ( z = ( {y}_{ij}^{b} - {y}_{s} ) tan α ) = {\underline{r}}_{ij}^{b} - i {\underline{p}}_{1} - j {\underline{p}}_{2} - {\underline{r}}_{b} \qquad ( 11 )$$

Here the parameters p₁, p₂ and r_{b} represent the optimized parameters for minimizing the penalty function in a 2D environment.

FIG. 18 shows a wedge 196 with a surface 195 and a true pitch 197 wherein the true channel is straight down perpendicular to the surface 195. Based on the image distortions the optimized transformation pitch is shown by 198 and 199. The fully hatched points represent the true intersection whereas the crosses show the apparent intersection through the image distortions depending on the z-direction.

Up to now only linear image distortions were considered. However the idea can be easily extended by including higher order distortions in the depth direction as shown by the following equation:

$$S = {\sum }_{b} {\sum }_{ij} {( {\underline{r}}_{ij}^{b} - i {\underline{p}}_{1} - j {\underline{p}}_{2} - {\underline{r}}_{b} - {\sum }_{ϑ} {w}_{ϑ} {\underline{v}}_{ϑ} ( {\underline{r}}_{ij}^{b} , ( {y}_{ij}^{b} - {y}_{s} ) tan α ) - {\underline{r}}_{T} ( ( {y}_{ij}^{b} - {y}_{s} ) tan α ) )}^{2} \qquad ( 12 )$$

where ν_{ϑ} (r, z) are distortion field basis functions either describing static (=z independent) SEM distortions or z-dependent SEM distortions (e.g., quadratic magnification in z) which are selected to be linearly independent but otherwise best adapted to the expected distortions. The factors w_{ϑ} are the weights to be determined.

The basis functions v could be the lowest order scan non-linearity.

$$\underline{v} ( \underline{r} , z ) = {x}^{2} {\hat{e}}_{x} \qquad ( 13 )$$

or could be a higher order magnification as shown by the following equation

$$\underline{v} ( \underline{r} , z ) = {z}^{2} \underline{r} \qquad ( 14 )$$

The basis function should be linearly independent.

It is desirable to acquire the wedge images with the same region of interest placement relative to the structures since then the banks are placed within the same repeatable SEM distortion field sector.

By minimizing equation (12) the higher order distortions can be considered. If the distortions are repeatable which were present for the generation of the representative ground truth structure or channel, then the parameters p₁, p₂ and r_{b} and w_{ϑ} can be determined only once and can then be used for all new wedge images to reconstruct the representative channel. Whenever the image generating method such as SEM is recalibrated then the validity of the parameters may be checked and possibly a recalibration can be carried out from the known ground truth representative channel.

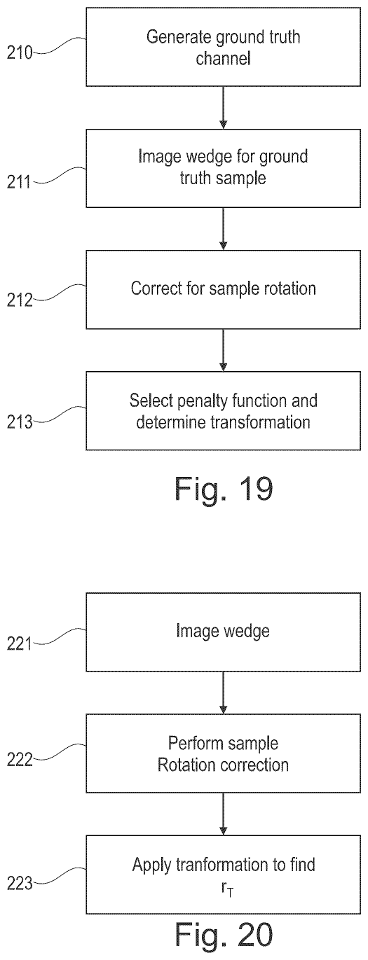

FIG. 19 shows a method which can be carried out to perform the above discussed calibration. The first step 210 the ground truth channel is generated. As discussed above this can be done from any reliable measurement method in which the structure can be determined with high precision such as 3D tomography or TEM. In step 211 at least one wedge image is generated for the sample where the ground truths channel has been determined. In step 212 the sample rotation can be corrected as discussed above in connection with FIGS. 9-11 and in step S213 the penalty function as can be selected and the optimal transformation can be determined by which the image representations are transformed such that they build the ground truth structure.

FIG. 20 shows the application of the determined transformation wherein in step 221 a wedge image is generated for a further sample for which the ground truth channel has not been determined by a reliable and precise image modality. In step 222 a sample rotation and a correction of the sample rotation is performed and in step 223 the transformation is applied using the parameters which were determined in step 213.

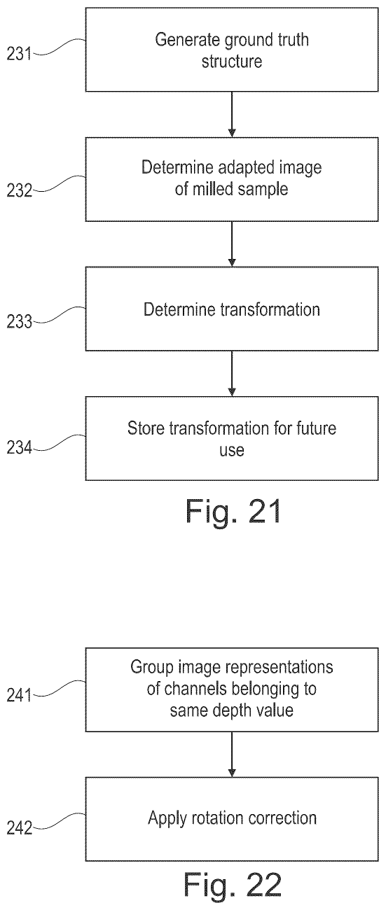

FIG. 21 discusses the steps of a method in which the transformation is determined and stored for future use in future semiconductor samples. In step 231 the ground truth structure is generated as already discussed in step 210 of FIG. 19 and as discussed above in connection with FIG. 12. Furthermore, in step 232 an adapted image of the milled sample is determined wherein this adapted image may already be corrected for any sample rotation. Based on the ground truth structure and the adapted image it is possible to determine the transformation by which the image representations at the different positions in the thickness direction are transformed to build the structure of the ground truth structure. Determining can include machine learning methods or other AI based procedures. Once the transformation and the parameters for the transformation are known the transformation is stored with the parameters in step 234 for future use so that for a further examination of a semiconductor sample it is not necessary anymore to generate the ground truth structure which is a rather time-consuming task. This was discussed in connection with FIG. 20 from where it can be deduced that the ground truth structure need not to be determined anymore.

FIG. 22 describes a schematic representation of how the sample rotation can be determined. In step 241 the image representations of the channels belonging to the same depth value are grouped together as discussed in connection with FIGS. 9 and 10 and the rotation correction is applied until they are aligned parallel to the edge of the sample. This adapted image is then used for determining the transformation.

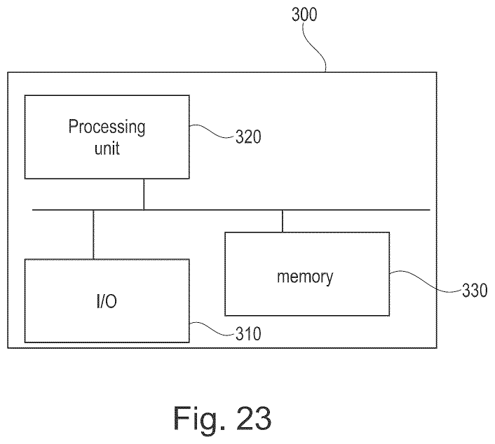

FIG. 23 shows a schematic architectural view of a processing entity 300 which could be part of control unit 2, control unit 19 or unit 16 discussed in connection with FIG. 2. However it should be understood that it might be also stand-alone unit. The processing entity 300 comprises an interface 310 configured to receive data and control messages from other entities and can be configured to transmit data and control messages to other entities. The interface 310 may be configured to receive the image data of the samples such as the wedge images. A processor or processing unit 320 is provided which is responsible for the operation of the processing entity. The processing unit 320 can comprise one or more processors and can carry out instructions stored on a memory 330, wherein the memory may include a read-only memory, a random access memory, a mass storage, a hard disk or the like. The memory can furthermore include suitable program code to be executed by the processing unit 320 so as to implement the above-described functionalities which are carried out for determining the transformation as discussed above.

From the following some general conclusions can be drawn which are described by the following clauses:

Clause 1. A method carried out at a processing entity, the method comprising:
determining a representative ground truth structure provided in a semiconductor sample having a plurality of structures extending mainly in a thickness direction of the sample in a region of interest containing the plurality of structures,
determining at least one adapted image of a milled or delayered sample which was obtained by milling the sample in a region containing the region of interest, wherein the at least one adapted image comprises image representations of the structures in the region of interest at different positions in the thickness direction,
determining a transformation by which the image representations at the different positions in the thickness direction of the structures build the ground truth structure,
storing the transformation for a future application of the transformation to a further sample having the plurality of structures.

Clause 2. The method of clause 1, wherein determining the transformation comprises solving an optimization problem in which a penalty function S is optimized in which the ground truth structure is compared to a combined structure obtained by folding back the image representations at the different positions in the thickness direction in order to build the combined structure.

Clause 3. The method of clause 2, wherein the penalty function contains explicitpitch parameters by which the image representations at the different positions are folded back to build the combined structure, wherein determining the transformation comprises determining the explicit pitch parameters and storing the transformation comprises storing the explicit pitch parameters.

Clause 4. The method of clause 2 or 3, wherein the penalty function contains an offset parameter r_{b} describing the spatial positions of different groups of structures, wherein determining the transformation comprises determining the offset parameter parameters and storing the transformation comprises storing the offset parameters.

Clause 5. The method of any of clauses 2 to 4, wherein the penalty function additionally contains distortion parameters reflecting higher order distortions in the thickness direction resulting from an image modality how the at least one adapted image was obtained, wherein determining the transformation comprises determining the distortion parameters and storing the transformation comprises storing the distortion parameters.

Clause 6. The method of clause 5, wherein the distortion parameters are only added to the penalty function when a remaining error occurring in solving the optimization problem only based on the explicitpitch parameters and optionally including the offset parameter is higher than a threshold error.

Clause 7. The method of any preceding clause, wherein the transformation is determined from a single adapted image which was taken from the milled sample which was obtained by milling an inclined edge into a top surface of the sample.

Clause 8. The method of any preceding clause, further comprising
obtaining at least one distorted image of the milled sample which was generated from the milled sample having an unwanted rotation of the milled sample
determining the unwanted sample rotation of the milled sample based on the at least one distorted image,
correcting the at least one distorted image of the milled sample based on the unwanted sample rotation in order to determine the at least one adapted image.

Clause 9. The method according to clause 8, wherein determining the unwanted sample rotation comprises:
grouping, in the at least one distorted image, all image representations of the structures in the region of interest at different positions in the thickness direction, together which have the same value in the thickness direction, to at least one grouped structure,
determining that the at least one grouped structure is not aligned parallel to a bounding edge of the milled sample extending perpendicular to the thickness direction,
aligning the at least grouped structure until it is parallel to the bounding edge in order to obtain the adapted image.

Clause 10. The method of any preceding clause, wherein the plurality of structures are channels extending in the semiconductor sample in the thickness direction.

Clause 11. The method of any preceding clause, wherein the representative ground truth structure is obtained at least one of the following:
a 3D tomography of the semiconductor sample,
a Transmission electron microscopy of the semiconductor sample,
Small angle x-ray scattering of the semiconductor sample.

Clause 12. The method of any preceding clause, wherein the transformation is applied to a further image of a second semiconductor sample having the plurality of structures extending mainly in the thickness direction of the sample.

Clause 13. The method of any preceding clause, wherein the determining and storing of the transformation is repeated when a configuration of an image modality was amended by which the at least one adapted image was obtained.

Clause 14. The method of any of clauses 3 to 13, wherein the transformation is learnt including the step of adapting weights in an artificial neural network.

Clause 15. A processing entity comprising a memory and at least one processor, the memory comprising instructions executable by the at least one processor, wherein the processing entity is configured to:
determine a representative ground truth structure provided in a semiconductor sample having a plurality of structures extending mainly in a thickness direction of the sample in a region of interest containing the plurality of structures,
determine at least one adapted image of a milled sample which was obtained by milling the sample in a region containing the region of interest, wherein the at least one adapted image comprises image representations of the structures in the region of interest at different positions in the thickness direction,
determine a transformation by which the image representations at the different positions in the thickness direction of the structures build the ground truth structure,
store the transformation for a future application of the transformation to a further sample having the plurality of structures.

Clause 16. The processing entity of clause 15, further being configured, for determining the transformation, to solve an optimization problem in which a penalty function S is optimized in which the ground truth structure is compared to a combined structure obtained by folding back the image representations at the different positions in the thickness direction in order to build the combined structure.

Clause 17. The processing entity of clause 16, wherein the penalty function contains explicit pitch parameters by which the image representations at the different positions are folded back to build the combined structure, wherein determining the transformation comprises determining the explicitpitch parameters and storing the transformation comprises storing the explicitpitch parameters.

Clause 18. The processing entity of clauses 16 or 17, wherein the penalty function contains an offset parameter r_{b} describing the spatial positions of different groups of structures, the processing entity being configured to determine the offset parameters and to store the offset parameters.

Clause 19. The processing entity of any of clauses 16 to 18, wherein the penalty function additionally contains distortion parameters reflecting higher order distortions in the thickness direction resulting from an image modality how the at least one adapted image was obtained, wherein the processing entity is configured, for determining the transformation, to determine the distortion parameters to store the distortion parameters.

Clause 20. The processing entity of clause 19, further being configured to only add the distortion parameters to the penalty function when a remaining error occurring in solving the optimization problem is higher than a threshold error.

Clause 21. The processor of any of clauses 15 to 20, further being operative to determine the transformation form a single image which was taken from the milled sample which was obtained by milling an inclined edge into a top surface of the sample.

Clause 22. The processor of any of clauses 15 to 21, further being configured to
obtain at least one distorted image of the milled sample which was generated from the milled sample having an unwanted rotation of the milled sample
determine the unwanted sample rotation of the milled sample based on the at least one distorted image,
correct the at least one distorted image of the milled sample based on the unwanted sample rotation in order to determine the at least one adapted image.

Clause 23. The processing entity of clause 22, further being configured, for determining the unwanted sample rotation, to
group, in the at least one distorted image, all image representations of the structures in the region of interest at different positions in the thickness direction, together which have the same value in the thickness direction, to at least one grouped structure,
determine that the at least one grouped structure is not aligned parallel to a bounding edge of the milled sample extending perpendicular to the thickness direction,
align the at least grouped structure until it is parallel to the bounding edge in order to obtain the adapted image.

Clause 24. The process entity of any of clauses 15 to 23, wherein the representative ground truth structure is obtained at least one of the following:
a 3D tomography of the semiconductor sample,
a Transmission electron microscopy of the semiconductor sample,
Small angle x-ray scattering of the semiconductor sample.

Clause 25. The processing entity of any of clauses 15 to 24, further being configured to apply the transformation to a further image of a second semiconductor sample having the plurality of structures extending mainly in the thickness direction of the sample.

Clause 26. The processing entity of any of clauses 15 to 25, further being configured to repeat the determining and storing of the transformation when a configuration of an image modality was amended by which the at least one adapted image was obtained.

Clause 27. A computer program comprising program code to be executed by at least one processing entity wherein execution of the program code causes the at least one processing entity to carry out a method as mentioned in any of clauses 1 to 14.

Clause 28. A carrier comprising the computer program of clause 27, wherein the carrier is one of an electronic signal, optical signal, radio signal, and computer readable storage medium.

What is claimed is:

1. A computer-implemented method, comprising:
determining a representative ground truth structure in a semiconductor sample, the semiconductor sample comprising a region of interest, the region of interest comprising a plurality of structures extending mainly in a thickness direction of the semiconductor sample;
determining an adapted image of a milled sample which was obtained by milling the semiconductor sample in a region comprising the region of interest, the adapted image comprising image representations of the structures in the region of interest at different positions in the thickness direction;
determining a transformation by which the image representations of the structures at the different positions in the thickness direction build the ground truth structure; and
storing the transformation for a future application of the transformation to a further sample having the plurality of structures.

2. The method of claim 1, wherein determining the transformation comprises solving an optimization problem in which a penalty function is optimized in which the ground truth structure is compared to a combined structure obtained by folding back the image representations at the different positions in the thickness direction in order to build the combined structure.

3. The method of claim 2, wherein:
the penalty function comprises explicit pitch parameters by which the image representations at the different positions are folded back to build the combined structure;
determining the transformation comprises determining the explicit pitch parameters; and
storing the transformation comprises storing the explicit pitch parameters.

4. The method of claim 2, wherein:
the penalty function comprises an offset parameter describing the spatial positions of different groups of structures;
determining the transformation comprises determining the offset parameter parameters; and
storing the transformation comprises storing the offset parameters.

5. The method of claim 2, wherein:
the penalty function comprises distortion parameters reflecting higher order distortions in the thickness direction resulting from an image modality relating to how the adapted image was obtained;
determining the transformation comprises determining the distortion parameters; and
storing the transformation comprises storing the distortion parameters.

6. The method of claim 5, wherein the distortion parameters are added to the penalty function only when a remaining error occurring in solving the optimization problem based only on the explicit pitch parameters is higher than a threshold error.

7. The method of claim 5, wherein the distortion parameters are added to the penalty function only when a remaining error occurring in solving the optimization problem based only on the explicit pitch parameters and the offset parameter is higher than a threshold error.

8. The method of claim 2, wherein:
the penalty function comprises explicit pitch parameters by which the image representations at the different positions are folded back to build the combined structure;
determining the transformation comprises determining the explicit pitch parameters;
storing the transformation comprises storing the explicit pitch parameters;
the penalty function further comprises an offset parameter describing the spatial positions of different groups of structures;
determining the transformation comprises determining the offset parameter parameters; and
storing the transformation comprises storing the offset parameters.

9. The method of claim 8, wherein:
the penalty function comprises distortion parameters reflecting higher order distortions in the thickness direction resulting from an image modality relating to how the adapted image was obtained;
determining the transformation comprises determining the distortion parameters; and
storing the transformation comprises storing the distortion parameters.

10. The method of claim 2, wherein:
the penalty function comprises explicit pitch parameters by which the image representations at the different positions are folded back to build the combined structure;
determining the transformation comprises determining the explicit pitch parameters;
storing the transformation comprises storing the explicit pitch parameters;
the penalty function comprises distortion parameters reflecting higher order distortions in the thickness direction resulting from an image modality relating to how the adapted image was obtained;
determining the transformation comprises determining the distortion parameters; and
storing the transformation comprises storing the distortion parameters.

11. The method of claim 1, wherein the transformation is determined from a single adapted image which was taken from the milled sample, and the milled sample was obtained by milling an inclined edge into a top surface of the sample.

12. The method of claim 1, further comprising:
obtaining a distorted image of the milled sample which was generated from the milled sample having an unwanted rotation of the milled sample;
determining the unwanted sample rotation of the milled sample based on the distorted image; and
correcting the distorted image of the milled sample based on the unwanted sample rotation to determine the adapted image.

13. The method of claim 12, wherein determining the unwanted sample rotation comprises:
grouping, in the distorted image, all image representations of the structures in the region of interest at different positions in the thickness direction together which have the same value in the thickness direction to a grouped structure;
determining that the grouped structure is not aligned parallel to a bounding edge of the milled sample extending perpendicular to the thickness direction; and
aligning the grouped structure until it is parallel to the bounding edge to obtain the adapted image.

14. The method of claim 1, wherein the plurality of structures comprise channels extending in the semiconductor sample in the thickness direction.

15. The method of claim 1, wherein obtaining the representative ground truth structure comprises using at least one technique selected from the group consisting of 3D tomography of the semiconductor sample, transmission electron microscopy of the semiconductor sample, and small angle x-ray scattering of the semiconductor sample.

16. The method of claim 1, wherein the transformation is applied to a further image of a second semiconductor sample having the plurality of structures extending mainly in the thickness direction of the sample.

17. The method of claim 1, wherein determining and storing of the transformation is repeated when a configuration of an image modality was amended by which the adapted image was obtained.

18. The method of claim 1, further comprising applying the transformation to the further sample comprising the plurality of structures.

19. One or more machine-readable hardware storage devices comprising instructions that are executable by one or more processing devices to perform operations comprising the method of claim 1.

20. A system comprising:
one or more processing devices; and
one or more machine-readable hardware storage devices comprising instructions that are executable by the one or more processing devices to perform operations comprising the method of claim 1.
